(19) United States
(12) Patent Application Publication
(10) Pub. No.: US 2025/0349797 A1
(43) Pub. Date: Nov. 13, 2025

(54) PACKAGE STRUCTURE AND METHOD FOR FORMING THE SAME

(71) Applicant: TAIWAN SEMICONDUCTOR MANUFACTURING COMPANY, LTD., Hsinchu (TW)

(72) Inventors: Chih-Chien PAN, Taipei City (TW); Pu WANG, Hsinchu City (TW); Li-Hui CHENG, New Taipei City (TW)

(73) Assignee: TAIWAN SEMICONDUCTOR MANUFACTURING COMPANY, LTD., Hsinchu (TW)

(21) Appl. No.: 18/658,078

(22) Filed: May 8, 2024

(51) Int. Cl. H01L 25/065; H01L 23/00; H01L 23/31; H01L 23/367; H01L 23/48; H01L 23/498

(52) U.S. Cl. CPC H01L 25/0655; H01L 23/3128; H01L 23/367; H01L 23/481; H01L 23/49838; H01L 24/16; H01L 24/32; H01L 24/73; H01L 24/96; H01L 24/97; H01L 2224/16225; H01L 2224/32225; H01L 2224/73204; H01L 2224/96; H01L 2224/97; H01L 2924/1815

(57) ABSTRACT

Embodiments of the present disclosure provide a package structure. The package structure includes a semiconductor die. An underfill material is below the semiconductor die and extends up to a sidewall of the semiconductor die. A molding compound surrounds the semiconductor die and the underfill material. An interface material is between the molding compound and the underfill material.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

As the demand for shrinking electronic devices has grown, a need for smaller and more creative packaging techniques of semiconductor dies has emerged. An example of such packaging systems is Package-on-Package (POP) technology. In a PoP device, a top semiconductor package is stacked on top of a bottom semiconductor package to provide a high level of integration and component density. Another example is a Chip-On-Wafer-On-Substrate (CoWoS) structure, where a semiconductor chip is attached to a wafer (e.g., an interposer) to form a Chip-On-Wafer (CoW) structure. The CoW structure is then attached to a substrate (e.g., a printed circuit board) to form a CoWoS structure. These and other advanced packaging technologies enable production of semiconductor devices with enhanced functionalities and small footprints.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 to 5B illustrate a method in various stages of forming a semiconductor die in accordance with some embodiments of the present disclosure.

FIGS. 6 to 16 illustrate a method in various stages of forming a package structure in accordance with some embodiments of the present disclosure.

FIGS. 17A, 17B, 17C, and 17D are package structures in accordance with some embodiments of the present disclosure.

FIGS. 18 to 28 illustrate a method in various stages of forming a package structure in accordance with some embodiments of the present disclosure.

FIGS. 29A, 29B, and 29C are package structures in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

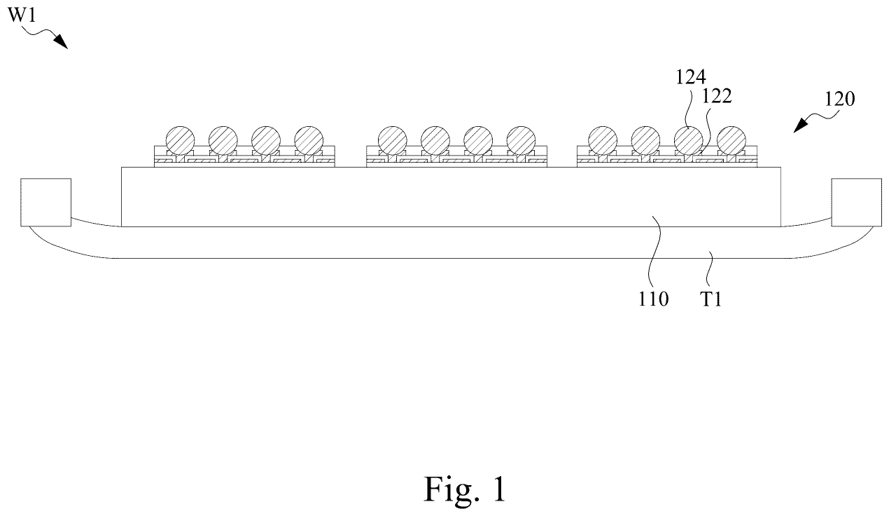

FIGS. 1 to 5B illustrate a method in various stages of forming a semiconductor die in accordance with some embodiments of the present disclosure. Although FIGS. 1 to 5B are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

Reference is made to FIG. 1. A semiconductor wafer W1 carried by a wafer grooving tape T1 is provided. The semiconductor wafer W1 may include a semiconductor substrate 110 and an interconnect structure 120, in which the interconnect structure 120 is disposed on the semiconductor substrate 110. In some embodiments, the semiconductor substrate 110 includes a crystalline silicon substrate. In some alternative embodiments, the semiconductor substrate 110 is made of some other suitable elemental semiconductor, such as diamond or germanium; a suitable compound semiconductor, such as gallium arsenide, silicon carbide, indium arsenide, or indium phosphide; or a suitable alloy semiconductor, such as silicon germanium carbide, gallium arsenic phosphide, or gallium indium phosphide.

The semiconductor wafer W1 may be an active interposer wafer including active components formed therein. The semiconductor substrate 110 may be a silicon substrate including active components (e.g., transistors or the like) and passive components (e.g., resistors, capacitors, inductors, or the like) formed therein. The active components and passive components may be formed in the semiconductor substrate 110 through front end of line (FEOL) fabrication processes of the interposer wafer W. The semiconductor substrate 110 may include various doped regions (e.g., p-type doped regions or n-type doped regions) formed through front end of line (FEOL) fabrication processes. The doped regions may be doped with p-type and/or n-type dopants. The doped regions may be doped with p-type dopants, such as boron or BF₂; n-type dopants, such as phosphorus or arsenic; and/or combinations thereof. The doped regions may be configured for an n-type FinFET, a p-type FinFET or the combination thereof. In some other embodiments, the doped regions may be configured for an n-type MOSFET, a p-type MOSFET or the combination thereof.

The interconnect structure 120 may include interconnect wirings (e.g., copper interconnect wirings) and dielectric layer stacked alternately, wherein the interconnect wirings of the interconnect structure 120 are electrically connected to the active components and/or the passive components in the semiconductor substrate 110. The interconnect structure 120 is formed through back end of line (BEOL) fabrication processes of the semiconductor wafer W1. The topmost interconnect wirings of the interconnect structure 120 may include conductive pads 122, and the conductive pads 122 may be aluminum pads, copper pads, or other suitable metallic pads. The interconnect structure 120 may further include a passivation layer disposed on a front surface or an active surface of the semiconductor wafer W1, wherein the conductive pads 122 are partially covered by the passivation layer. In other words, the conductive pads 122 are partially revealed from the openings defined in the passivation layer. The passivation layer may be a silicon oxide layer, a silicon nitride layer, a silicon oxy-nitride layer, or a dielectric layer formed by other suitable inorganic dielectric materials. The interconnect structure 120 may further include a post-passivation layer (not shown) formed over the passivation layer, wherein the post-passivation layer covers the passivation layer and the conductive pads 122, the post-passivation layer includes contact openings, and the conductive pads 122 are partially revealed from the contact openings defined in the post passivation layer. The post-passivation layer may be a polyimide (PI) layer, a PBO layer, or a dielectric layer formed by other suitable organic dielectric materials. In some alternative embodiments, the post-passivation layer is omitted.

In some embodiments, a wafer level bumping process is performed on the interconnect structure 120 of the semiconductor wafer W1 such that connectors 124 are formed on the conductive pads 122. The conductive pads 122 of the interconnect structure 120 may be bump pads, and the connectors 124 may be micro bumps landing on the conductive pads 122. In some embodiments, the connectors 124 may include Cu/Ni/Au bumps, Cu/Ni bumps, Cu/Ni/Au/SnAg bumps, Cu/Ni/SnAg bumps, or the like.

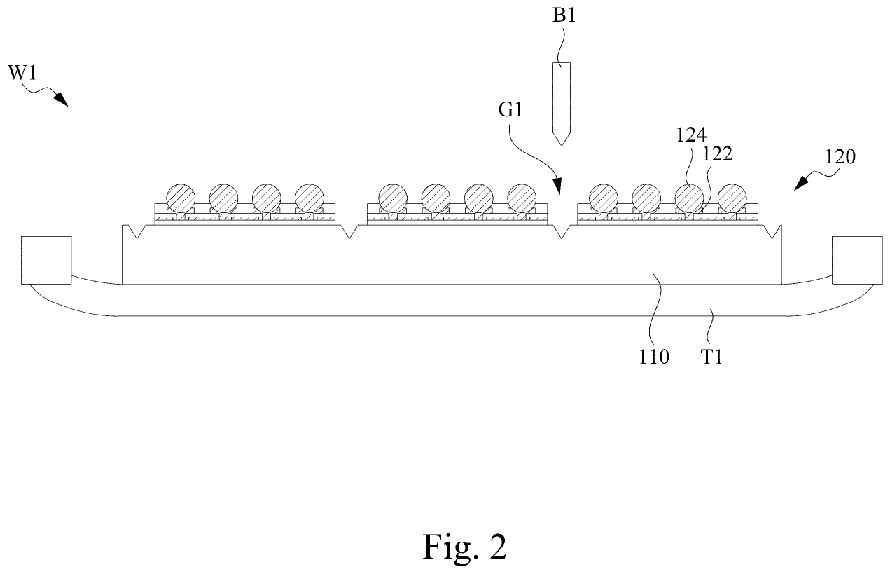

Reference is made to FIG. 2. A bevel cutting process is performed to form V-shaped grooves G1 on the front surface of the semiconductor substrate 110 of the semiconductor wafer W1. The V-shaped grooves G1 may be formed by a wafer dicing process performed along scribe lines of the semiconductor substrate 110 of the semiconductor wafer W1. The V-shaped grooves G1 may be formed through a V-shaped dicing blade B1.

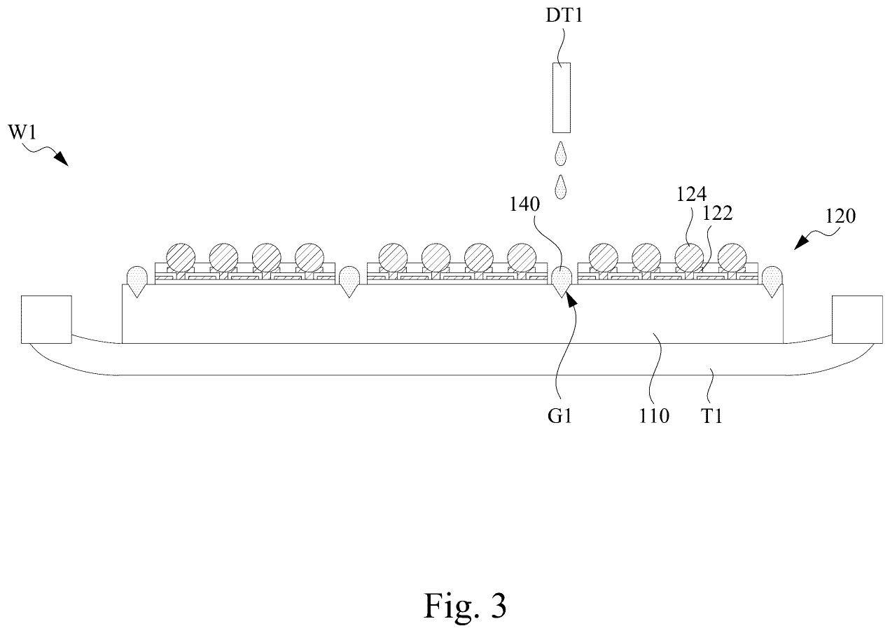

Reference is made to FIG. 3. Buffer materials 140 are dispensed in the grooves G1, respectively. In some embodiments, the buffer materials 140 are dispensed using a dispensing tool DT1. For example, the dispensing tool DT1 is moved to a position vertically above a groove G1, and then a buffer material 140 is dispensed from the dispensing tool DT1 and filling the groove G1. The dispensing tool DT1 is then moved to another position above a corresponding groove G1, and a buffer material 140 is dispensed from the dispensing tool DT1 and filling the groove G1. In some embodiments, the buffer materials 140 are dispensed at the regions around the grooves G1, such that the buffer materials 140 fill the grooves G1 and slight extend to the front surface of the semiconductor substrate 110. That is, at least a portion of the front surface of the semiconductor substrate 110 may be free of coverage by the buffer materials 140. In some embodiments, the buffer materials 140 may not be dispensed over other structures of the semiconductor wafer W1, such as the connectors 124 of the interconnect structure 120.

In some embodiments, the buffer materials 140 may include die attach film (DAF), polyimide (PI), acrylic base polymer, epoxy base polymer, or the like. In the embodiments where the buffer materials 140 are made of die attach film (DAF), the DAF may be liquid, e.g., a thick liquid, when applied but forms a solid at room temperature. The DAF material may become semi-liquid when heated and may become sticky to function as an adhesive at elevated temperatures. The DAF may comprise a polymer-based film that functions as an adhesive when heated, in some embodiments, for example. The DAF may comprise a thermoplastic material, such as epoxy resin, phenol resin, or poly-olefin, as examples, although alternatively, other thermoplastic materials or polymers compatible with semiconductor processing environments may be used. In some embodiments, the DAF in liquid form may be dispensed in the respective groove G1. Afterwards, an UV curing process is performed to slightly solidify the DAF. A thermal curing process may then be performed to solidify the DAF.

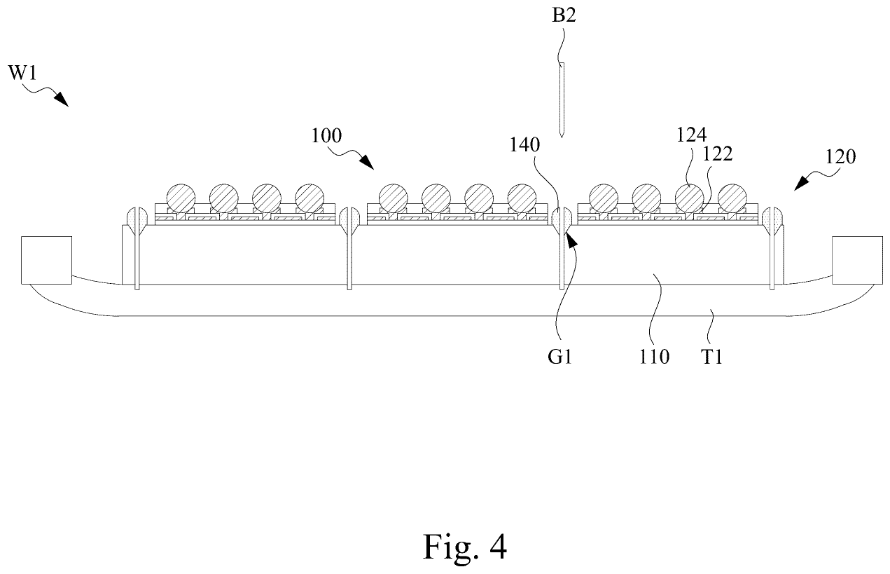

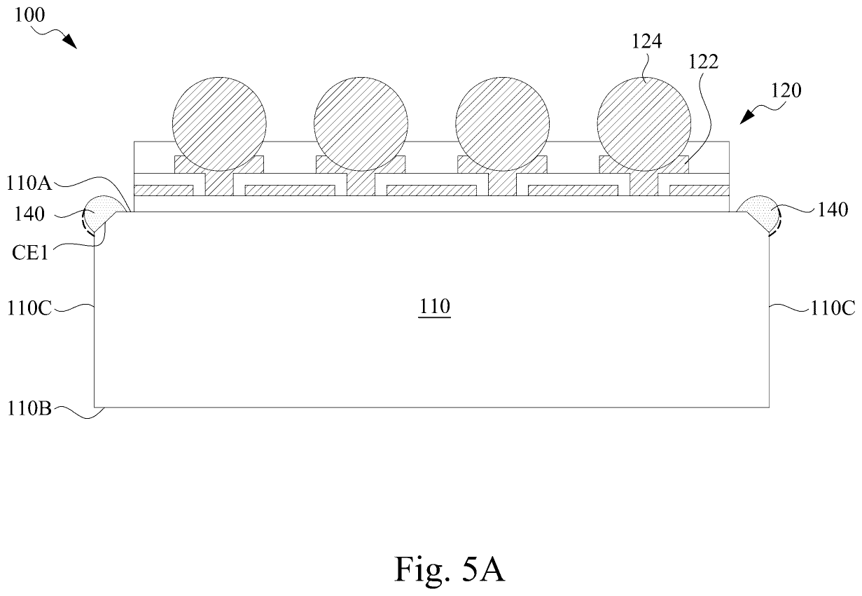

Reference is made to FIG. 4. After the buffer materials 140 are formed, a full cutting process (e.g., singulation process) is performed along the V-shaped grooves G1 on the front surface of the semiconductor substrate 110 such that singulated semiconductor dies 100 are obtained. The full cutting process may cut through the buffer materials 140. In some embodiments, the full cutting process may be performed through a dicing blade B2 along the V-shaped grooves G1. In some embodiments, the width of the dicing blade B2 is smaller than the width of each of the buffer materials 140. This will result in that the buffer materials 140 may remain on corners of the singulated semiconductor dies 100 after the full cutting process is complete.

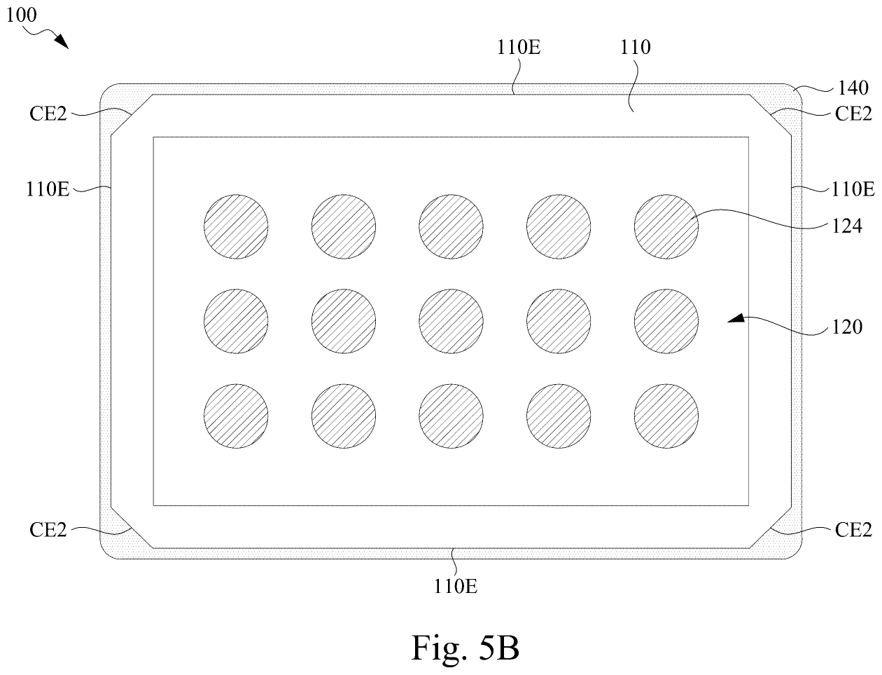

Reference is made to FIGS. 5A and 5B, in which FIG. 5A is a cross-sectional view of the singulated semiconductor die 100, and FIG. 5B is a top view of the singulated semiconductor die 100. As shown in the cross-sectional view of FIG. 5A, the semiconductor die 100 includes a semiconductor substrate 110, which includes a first surface 110A, a second surface 110B opposite to the first surface 110A, and sidewalls 110C connecting the first surface 110A and the second surface 110B. The semiconductor die 100 also includes an interconnect structure 120 disposed on the first surface 110A of the semiconductor substrate 110.

In some embodiments, the semiconductor substrate 110 includes chamfered edges CE1 on opposite ends of the first surface 110A of the semiconductor substrate 110, in which the chamfered edges CE are resulted from the bevel cutting process as discussed in FIG. 2 (e.g., the V-Shaped grooves G1). In greater detail, the chamfered edge CE1 is an inclined surface that connects the first surface 110A of the semiconductor substrate 110 and the respective sidewall 110C of the semiconductor substrate 110. In some embodiments, the first surface 110A, the second surface 110B, the sidewalls 110C, and the chamfered edge CE1 are silicon surface.

The semiconductor die 100 also includes buffer materials 140 covering the respective chamfered edges CE1. Moreover, as mentioned above in FIG. 3, the buffer materials 140 may extend to the first surface 110A of the semiconductor substrate 110, while portions of the first surface 110A of the semiconductor substrate 110 are free of coverage by the buffer materials 140. With respect to the second surface 110B, because no V-shaped grooves are formed on the second surface 110B during forming the semiconductor die 100, there may not be chamfered edges on opposite ends of the second surface 110B. That is, the second surface 110B may intersect with the sidewalls 110C at a substantially right angle.

In some embodiments, the sidewalls 110C of the semiconductor substrate 110 may be free of coverage by the buffer materials 140. This is because the sidewalls 110C of the semiconductor substrate 110 are formed through the full cutting process as discussed in FIG. 4, while the buffer materials 140 have already been formed prior to performing the full cutting process. However, in other embodiments, the buffer materials 140 may slightly extend to the respectively sidewalls 110C of the semiconductor substrate 110 as shown by dash line. This is because gravity force may cause the buffer materials 140 to drop downwards from the chamfered edges CE1 to the sidewalls 110C. In such embodiments, the contact area (or width) between the buffer material 140 and the first surface 110A may be greater than the contact area (or width) between the buffer material 140 and the sidewall 110C. In some embodiments, an entirety of the chamfered edges CE1 may be covered by the buffer materials 140.

As shown in the top view of FIG. 5B, the semiconductor substrate 110 may include a substantially rectangular top profile, which includes four sidewalls 110E. In some embodiments, the semiconductor substrate 110 also includes chamfered edges CE2, in which each of the chamfered edges CE2 connects adjacent two sidewalls 110E. Is it noted that the chamfered edges CE2 are also resulted from the bevel cutting process as discussed in FIG. 2. Although in the cross-sectional view of FIG. 5A there are two separated buffer materials 140, in the top view of FIG. 5A the buffer materials 140 are actually a single piece having a rectangular ring shape top profile that surrounds the semiconductor substrate 110. In greater detail, the buffer material 140 may be in contact with all of the sidewalls 110E and the chamfered edges CE2 from the top view of FIG. 5B.

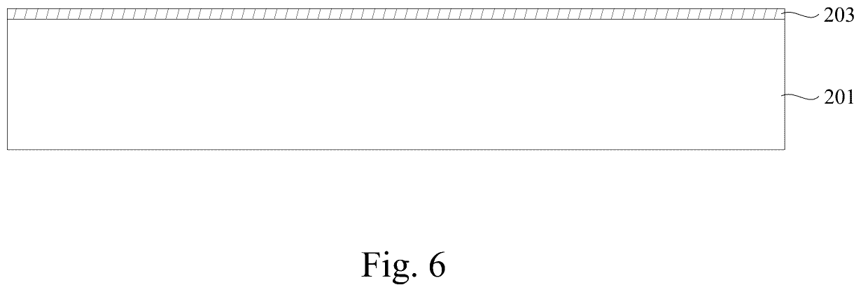

FIGS. 6 to 16 illustrate a method in various stages of forming a package structure in accordance with some embodiments of the present disclosure. Although FIGS. 6 to 16 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

Reference is made to FIG. 6. Shown there is a carrier substrate 201, and a release layer 203 is formed over the carrier substrate 201. In some embodiments, the carrier substrate 201 includes glass, ceramic, or other suitable material to provide structural support during the formation of various features in device package. The release layer 203 may be formed of a polymer-based material, which may be removed along with the carrier substrate 201 in subsequent operations. In some embodiments, the release layer 203 is an epoxy-based thermal-release material, which loses its adhesive property when heated, such as a light-to-heat conversion (LTHC) release coating. In some embodiments, the release layer 203 may be an ultraviolet (UV) glue, which loses its adhesive property when exposed to UV light. The release layer 203 can be a liquid that is dispensed and cured, a laminate film that is disposed onto the carrier substrate 201, or a layer of another form and method of disposition.

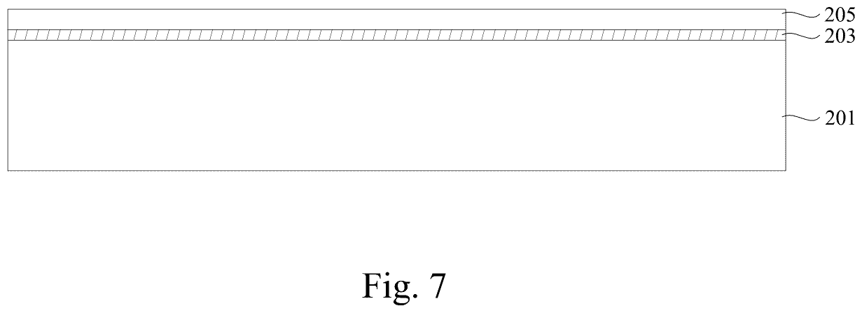

Reference is made to FIG. 7. An adhesive layer 205 is formed over the release layer 203. In some embodiments, the adhesive layer 205 may be a die attach film (DAF) which includes a polymer and in some embodiments comprises a thermoplastic material. The DAF may be liquid, e.g., a thick liquid, when applied but forms a solid at room temperature. The DAF material may become semi-liquid when heated and may become sticky to function as an adhesive at elevated temperatures. The DAF may comprise a polymer-based film that functions as an adhesive when heated, in some embodiments, for example. The DAF may comprise a thermoplastic material, such as epoxy resin, phenol resin, or poly-olefin, as examples, although alternatively, other thermoplastic materials or polymers compatible with semiconductor processing environments may be used.

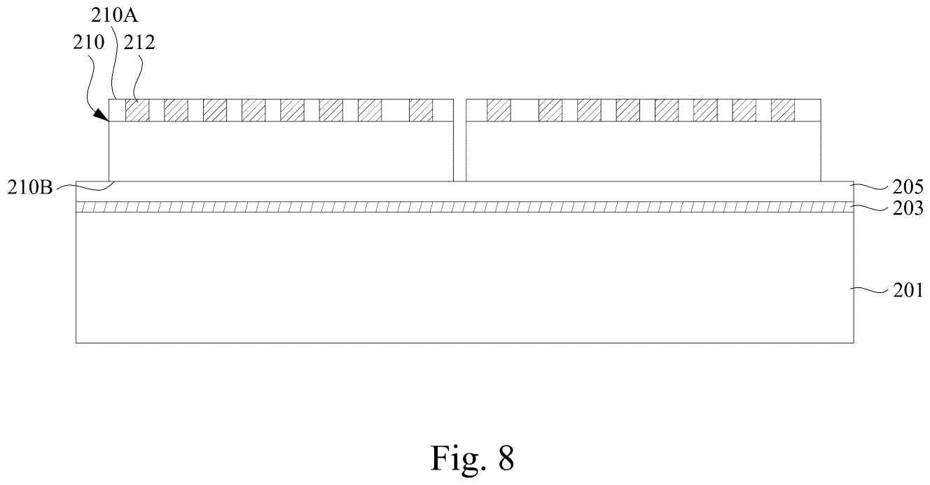

Reference is made to FIG. 8. Semiconductor dies 210 are attached to the adhesive layer 205. Several dozen semiconductor dies 210 or several hundred semiconductor dies 210 or more may be attached to the adhesive layer 205, depending on the size of the semiconductor dies 210, the size of carrier substrate 201, and the practical application, as examples. The semiconductor dies 210 have a first side 210A and a second side 210B opposite to the first side 210A. The semiconductor dies 210 may include semiconductor devices or integrated circuits that have been previously manufactured on a semiconductive substrate. The semiconductor dies 210 may comprise one or more layers of electrical circuitry and/or electronic functions formed thereon, and may include conductive lines, vias, capacitors, diodes, transistors, resistors, inductors, and/or other electrical components, for example (not shown). The semiconductor dies 210 have been singulated from the substrate they were manufactured on and are ready for packaging. A pick and place machine may be used to place the semiconductor dies 210 in predetermined locations on the carrier substrate 201, for example. The second sides 210B of the dies 210 are attached to the adhesive layer 205. In some embodiments, the semiconductor dies 210 may include a plurality of conductive features 212 exposed through the first sides 210A.

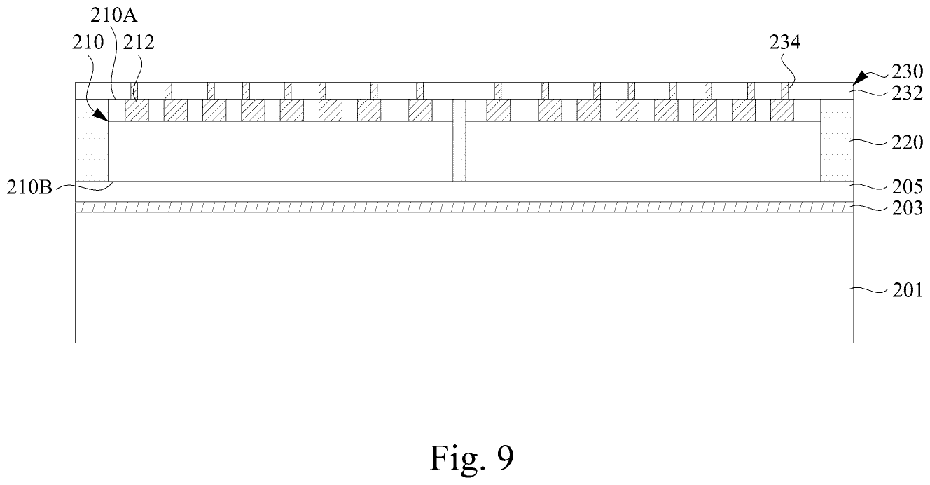

Reference is made to FIG. 9. A molding compound 220 may be molded onto the adhesive layer 205 over the carrier substrate 201 and surrounding the semiconductor dies 210. The top surface of molding compound 220 may be formed higher than, level with, or slightly lower than, the first sides 210A of the semiconductor dies 210. A grinding process may be performed to planarize the first sides 210A of the semiconductor dies 210, so that any unevenness in the first sides 210A of the semiconductor dies 210 may be at least reduced, and possibly substantially eliminated. If the molding compound 220 includes portions on the first sides 210A of the semiconductor dies 210, these portions of molding compound 220 may also be removed by the grinding process. Accordingly, the top surfaces of the remaining portions of the molding compound 220 are level with first sides 210A of the semiconductor dies 210. Furthermore, the height or thickness of the plurality of semiconductor dies 210 may also be reduced to a desirable height through the grinding process.

A redistribution layer 230 is then formed over the molding compound 220. The redistribution layer 230 may include a dielectric layer 232 and conductive features 234 disposed in the dielectric layer 232. In some embodiments, the conductive features 234 may be electrically coupled to the conductive features 212 of the semiconductor dies 210. The redistribution layer 230 can include any number of dielectric layer(s) 232 and any number of conductive feature(s) 234.

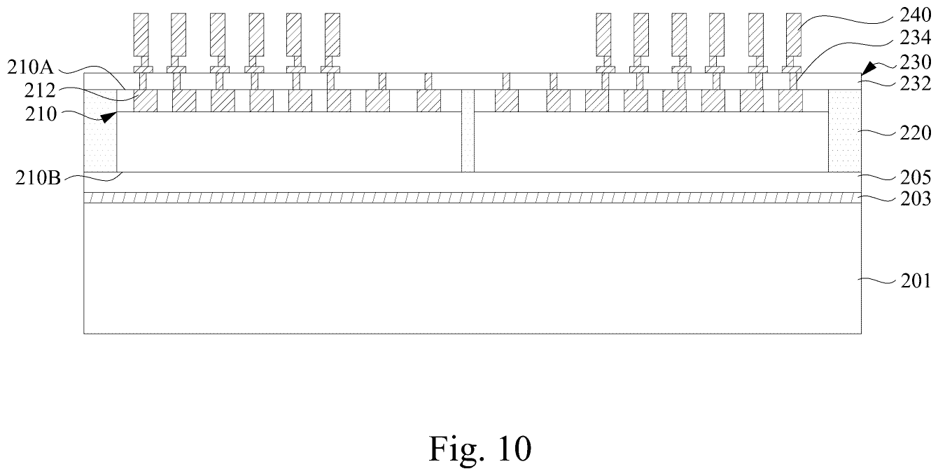

Reference is made to FIG. 10. Conductive vias 240 are formed over the redistribution layer 230 and electrically coupled to the respective conductive features 234 in the redistribution layer 230. As an example to form the conductive vias 240, a seed layer (not shown) is formed over the redistribution layer 230. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, PVD or the like. A photo resist is then formed and patterned on the seed layer. The photo resist may be formed by spin coating or the like and may be exposed to light for patterning. The patterning forms openings through the photo resist to expose the seed layer. A conductive material is formed in the openings of the photo resist and on the exposed portions of the seed layer. The conductive material may be formed by plating, such as electroplating or electroless plating, or the like. The conductive material may comprise a metal, like copper, titanium, tungsten, aluminum, or the like. Then, the photo resist and portions of the seed layer on which the conductive material is not formed are removed. The photo resist may be removed by an acceptable ashing or stripping process, such as using an oxygen plasma or the like. Once the photo resist is removed, exposed portions of the seed layer are removed, such as by using an acceptable etching process, such as by wet or dry etching. The remaining portions of the seed layer and conductive material form the conductive vias 240.

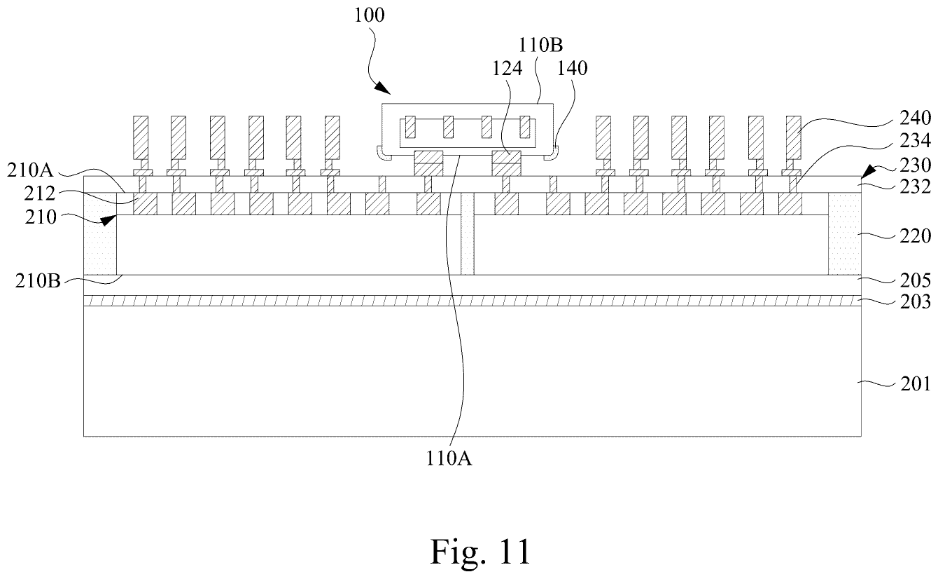

Reference is made to FIG. 11. A semiconductor die 100 is attached to the redistribution layer 230. The structural details of the semiconductor die 100 have been discussed above with respect to FIGS. 1 to 5B, and thus relevant details will not be repeated for brevity. In some embodiments, the semiconductor die 100 as shown in FIG. 5A may be flipped over by 180 degrees, and the semiconductor die 100 may be placed onto the redistribution layer 230 using, e.g., a pick-and-place tool, however, any other method of placing the semiconductor die 100 may also be utilized. As a result, the connectors 124 of the semiconductor die 100 are electrically connected to the respective conductive features 234 in the redistribution layer 230. In some embodiments, the first surface 110A of the semiconductor substrate 110 on which the buffer materials 140 are disposed faces the redistribution layer 230 after the semiconductor die 100 is attached to the redistribution layer 230.

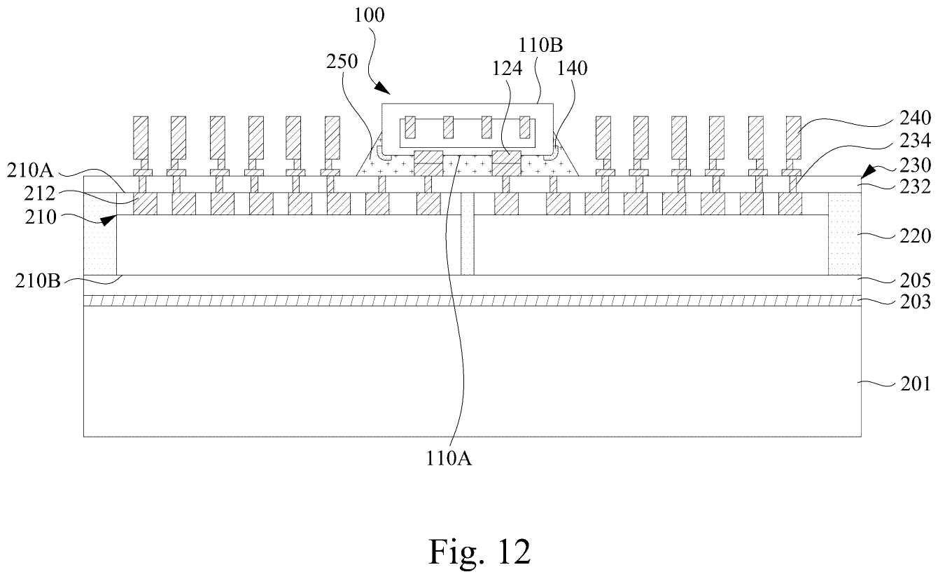

Reference is made to FIG. 12. An underfill material 250 is dispensed into the gaps between the semiconductor die 100 and the redistribution layer 230. The underfill material 250 surrounds the connectors 124, and may extend up along sidewalls 110C of the semiconductor substrate 110 of the semiconductor die 100. In some embodiments, the underfill material 250 may be in contact with the buffer materials 140 on the semiconductor substrate 110. In greater detail, the underfill material 250 may extend from the sidewall 110C of the semiconductor substrate 110, passing through the buffer materials 140, to the first surface 110A of the semiconductor substrate 110. The underfill material 250 may be acceptable material, such as a polymer, epoxy, molding underfill, or the like. The underfill material 250 may be formed by a capillary flow process after the semiconductor die 100 are attached to the redistribution layer 230.

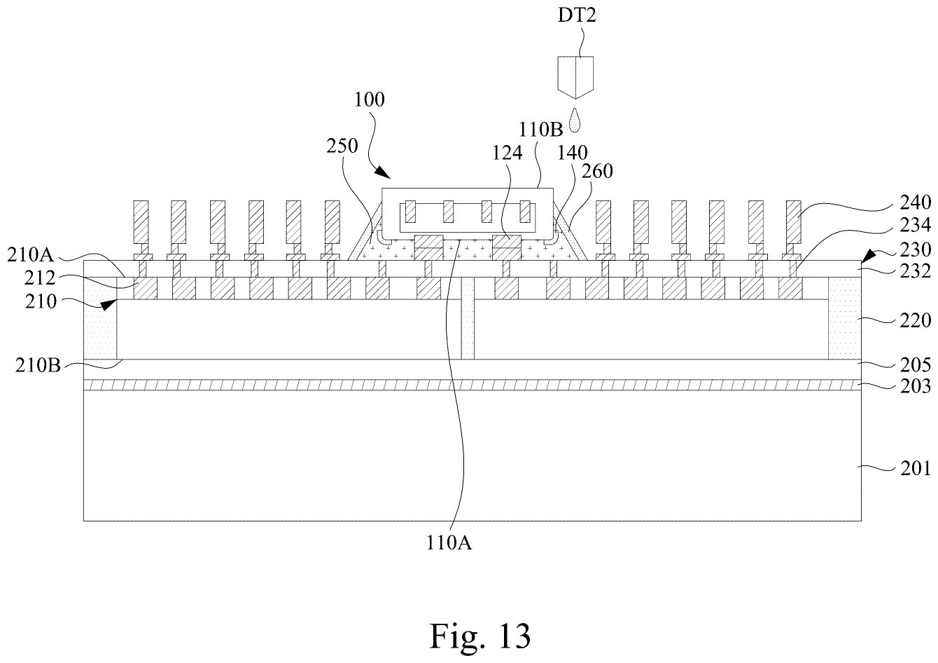

Reference is made to FIG. 13. Interface materials 260 are dispensed along the exposed surfaces of the underfill material 250. In some embodiments, the interface materials 260 are dispensed using a dispensing tool DT2. For example, the dispensing tool DT2 is moved to a position vertically above the exposed surface of the underfill material 250, and then an interface material 260 is dispensed from the dispensing tool DT2 and covering the exposed surface of the underfill material 250. The dispensing tool DT2 is then moved to another position above another exposed surface of the underfill material 250, and an interface material 260 is dispensed from the dispensing tool DT2 and covering the another exposed surface of the underfill material 250. In some embodiments, the interface materials 260 may extend from the sidewalls 110C of the semiconductor substrate 110 of the semiconductor die 100, passing through the respective surfaces of the underfill material 250, to the surface of the redistribution layer 230.

In some embodiments, the interface materials 260 may include die attach film (DAF), polyimide (PI), acrylic base polymer, epoxy base polymer, or the like. In the embodiments where the interface materials 260 are made of die attach film (DAF), the die attach films in liquid form are dispensed along the surfaces of the underfill material 250. Afterwards, an UV curing process is performed to slightly solidify the die attach films. A thermal curing process may then be performed to solidify the die attach films. In some embodiments, the interface materials 260 and the buffer materials 140 may be made of a same material. In some embodiments, the interface materials 260 and the buffer materials 140 may be made of materials that are different from the material of the underfill material 250.

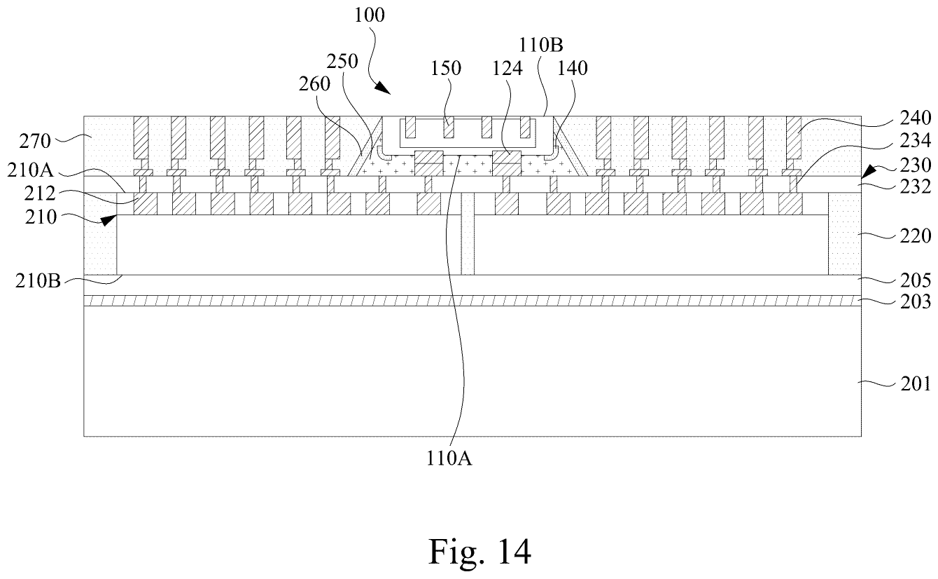

Reference is made to FIG. 14. Molding compound 270 is formed filling the gaps between neighboring conductive vias 240 and the gaps between the conductive vias 240 and the semiconductor die 100. In some embodiments, the top surface of molding compound 270 is higher than the top ends of conductive vias 240 and the top surfaces of semiconductor die 100. Then, a planarization process such as a mechanical grinding step is performed to thin the molding compound 270 and the semiconductor substrate 110 of the semiconductor die 100. That is, both the molding compound 270 and the semiconductor substrate 110 of the semiconductor die 100 are polished. In some embodiments, the planarization process is performed until the conductive vias 240 and the conductive features 150 in the semiconductor substrate 110 of the semiconductor die 100 are exposed. The conductive vias 240 are alternatively referred to as through-mold-vias (TMVs) hereinafter since they penetrate through the molding compound 270. In some embodiments, the molding compound 270 may include a polymer, a resin, an epoxy, or the like.

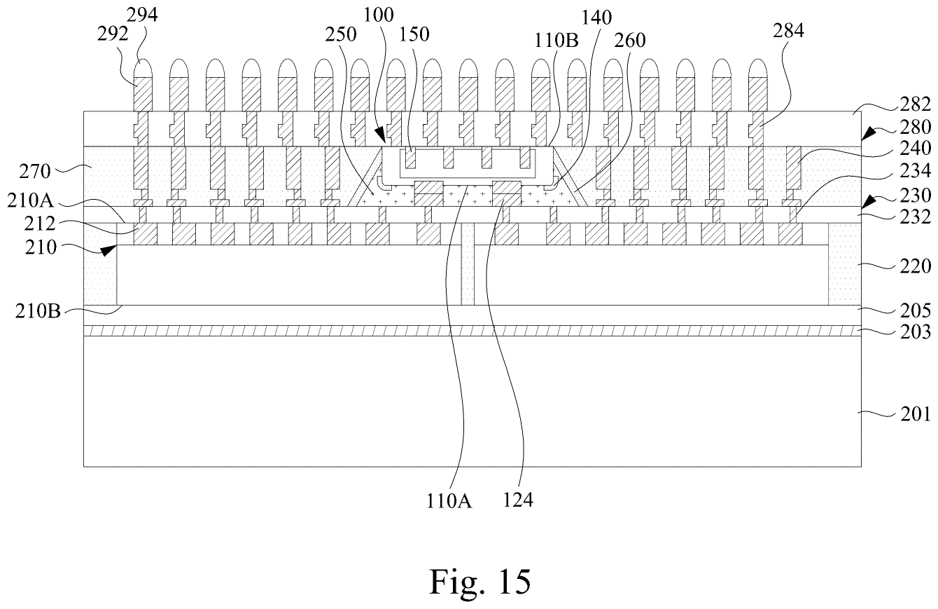

Reference is made to FIG. 15. A redistribution layer 280 is then formed over the molding compound 270. The redistribution layer 280 may include a dielectric layer 282 and conductive features 284 disposed in the dielectric layer 282. In some embodiments, the conductive features 284 may be electrically coupled to the conductive vias 240 and the conductive features 150 in the semiconductor substrate 110 of the semiconductor die 100. In some embodiments, the redistribution layer 280 can include any number of dielectric layer(s) 282 and any number of conductive feature(s) 284.

External connectors 292 may be formed over the redistribution layer 280 and may be electrically coupled to the conductive features 284 in the redistribution layer 280. In some embodiments, the external connectors 292 are copper pillars. Solders 294 are formed on the top surfaces of the respective external connectors 292. The dimensions of the external connectors 292 and solders 294 illustrated above are merely non-limiting examples, any other suitable dimensions for the external connectors 292 and solders 294 are possible and are fully intended to be included within the scope of the present disclosure.

In some embodiments, the external connectors 292 may be contact bumps such as controlled collapse chip connection (C4) bumps and may comprise a material such as tin, or other suitable materials, such as silver or copper. In an embodiment in which the external connectors 292 are tin solder bumps, the external connectors 292 may be formed by initially forming a layer of tin through any suitable method such as evaporation, electroplating, printing, solder transfer, ball placement, etc.

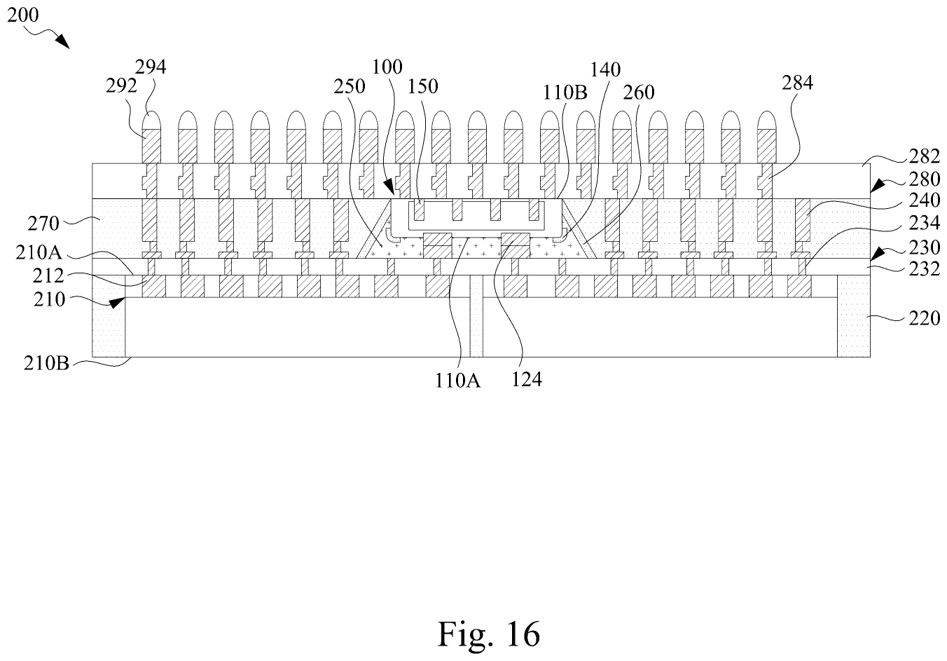

Reference is made to FIG. 16. The carrier substrate 201 and the release layer 203 are removed. In some embodiments, the removal may be accomplished by projecting a light such as a laser light or an UV light on the release layer 203 so that the release layer 203 decomposes under the heat of the light and the carrier substrate 201 is debonded. After the carrier substrate 201 is de-bonded, a cleaning process (e.g., a DAF cleaning process) may be performed to remove remaining portions of the adhesive layer 205, such that the semiconductor dies 210 and the molding compound 220 are exposed. As a result, a package structure 200 is formed.

During the formation of the package structure 200, the underfill material 250 may be formed covering the corners of the semiconductor substrate 110 of the semiconductor die 100. However, due to coefficient of thermal expansion (CTE) difference between the underfill material 250 and the material of the semiconductor substrate 110, material expansion may induce high stress at the corners of the semiconductor substrate 110. As a result, cracking or delamination may occur at the interface between the underfill material 250 and the corners of the semiconductor substrate 110. Embodiments of the present disclosure provide a method by forming buffer materials 140 at the corners of the semiconductor substrate 110 of the semiconductor die 100. The buffer materials 140 may release the stress at the corners of the semiconductor substrate 110, which in turn will reduce the possibility of cracking or delamination at these regions.

Similarly, the molding compound 270 is formed surrounding the underfill material 250. Due to coefficient of thermal expansion (CTE) difference between the underfill material 250 and molding compound 270, material expansion may result in cracking or delamination at the interface between the underfill material 250 and the molding compound 270. Embodiments of the present disclosure provide a method by forming interface materials 260 between the underfill material 250 and the molding compound 270. The interface materials 260 may release the stress at the interface between the underfill material 250 and the molding compound 270, which in turn will reduce the possibility of cracking or delamination at these regions. Moreover, the interface materials 260 may also improve the adhesion between the underfill material 250 and the molding compound 270, and will further improve the packaging quality.

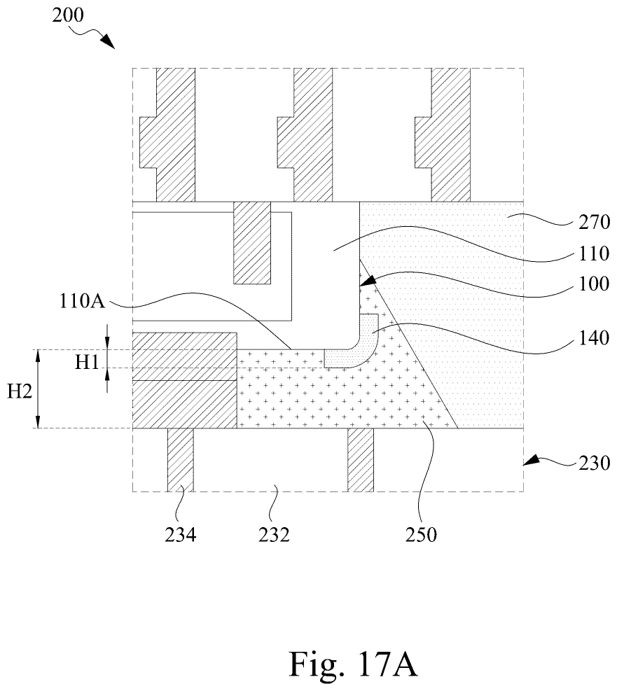

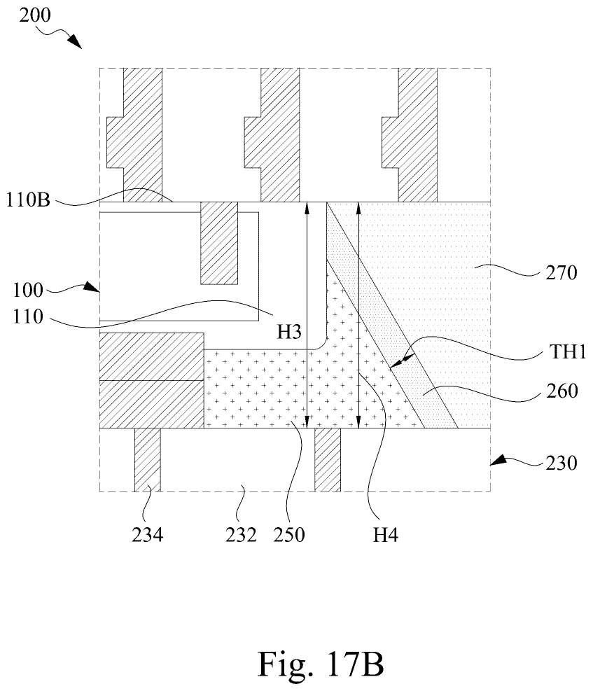

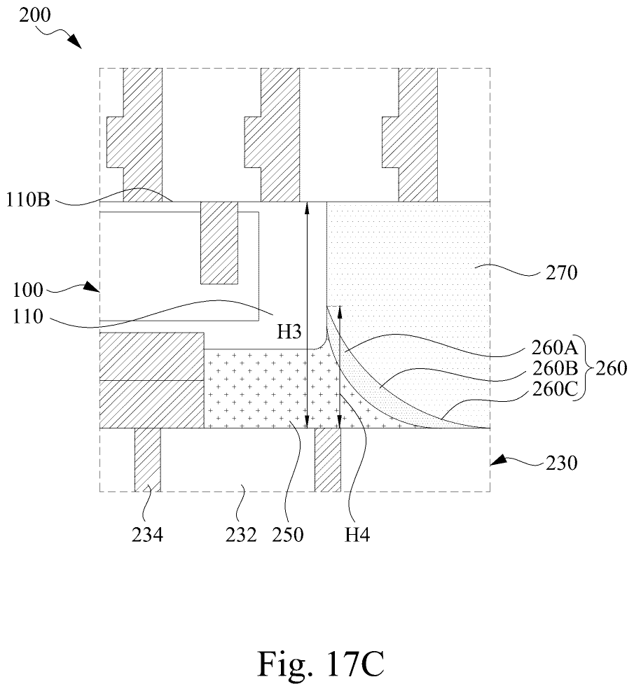

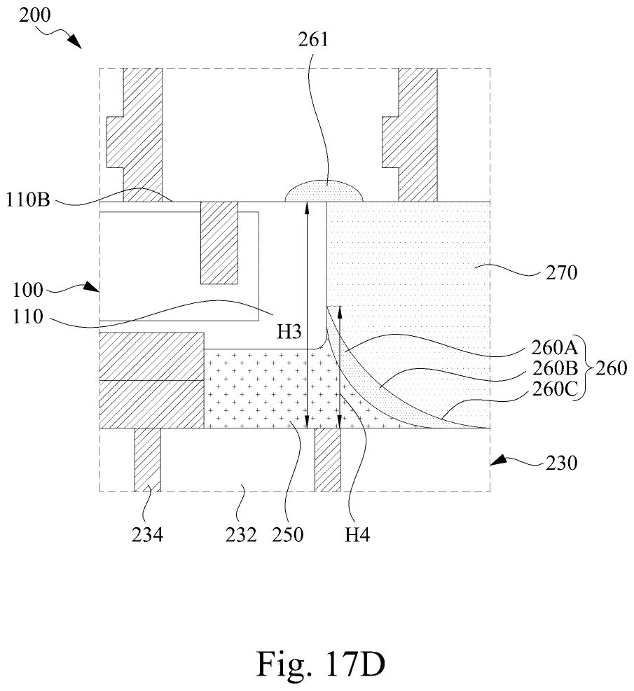

FIGS. 17A, 17B, 17C, and 17D are package structures in accordance with some embodiments of the present disclosure. In particular, FIGS. 17A, 17B, 17C, and 17D are enlarged view of the package structure 200 of FIG. 16.

FIG. 17A illustrates some embodiments where the interface materials 260 are absent in the package structure 200. For example, the process as discussed in FIG. 13 may be omitted, and the resulting structure is shown in FIG. 17A. Accordingly, the molding compound 270 may be in contact with the underfill material 250.

In the enlarged view of FIG. 17A, the portion of the buffer material 140 below the first surface 110A of the semiconductor substrate 110 of the semiconductor die 100 has a height H1. The distance between the first surface 110A of the semiconductor substrate 110 and the redistribution layer 230 is referred to as height H2. In some embodiments, the height H1 is in a range from about 0.5 μm to about 30 μm. If the height H1 is too small (e.g., much smaller than 0.5 μm), the buffer material 140 may not be able to prevent cracking or delamination at the corner of the semiconductor substrate 110 of the semiconductor die 100. If the height H1 is too large (e.g., much greater than 30 μm), the buffer material 140 may be too thick, and may adversely affect the process of mounting the semiconductor die 100 on the redistribution layer 230. The height H1 may be smaller than or equal to the height H2. In some embodiments where the height H1 is smaller than the height H2, the buffer material 140 may be vertically separated from the redistribution layer 230. In some embodiments where the height H1 is equal to the height H2, the buffer material 140 may be in contact with the redistribution layer 230.

FIGS. 17B and 17C illustrate some embodiments where the buffer materials 140 are absent in the package structure 200. For example, the process as discussed in FIG. 3 may be omitted, and the resulting structure is shown in FIGS. 17B and 17C. Accordingly, the underfill material 250 may cover the corner of the semiconductor substrate 110 of the semiconductor die 100.

The interface material 260 has a thickness TH1. The distance between the second surface 110B of the semiconductor substrate 110 and the redistribution layer 230 is referred to as height H3. The distance between the topmost end of the interface material 260 and the redistribution layer 230 is referred to as height H4. In some embodiments, the thickness TH1 is in a range from about 0.1 μm to about 100 μm. If the thickness TH1 is too small (e.g., much smaller than 0.1 μm), the interface material 260 may not be able to prevent cracking or delamination at the interface between the underfill material 250 and the molding compound 270. If the thickness TH1 is too large (e.g., much greater than 100 μm), no significant improvement is obtained. The height H4 may be smaller than or equal to the height H3. In some embodiments where the height H4 is smaller than the height H3, the topmost end of the interface material 260 may be lower than the second surface 110B of the semiconductor substrate 110, as shown in FIG. 17C. In some embodiments where the height H4 is equal to the height H3, the topmost end of the interface material 260 may be level with the second surface 110B of the semiconductor substrate 110, as shown in FIG. 17B.

Moreover, in the enlarged view of FIG. 17C, underfill material 250 may include a concave surface, and the interface material 260 may extends along the concave surface of the underfill material 250. In such embodiments, the interface material 260 may include thickness varication. For example, the interface material 260 may include a top portion 260A, a middle portion 260B, and a bottom portion 260C. In some embodiments, the middle portion 260B is thicker than the top portion 260A and the bottom portion 260C.

FIG. 17D is similar to FIG. 17C, the difference between FIGS. 17C and 17D are that in the embodiments of FIG. 17D, a buffer material 261 may be additional formed extending from the second surface 110B of the semiconductor substrate 110, passing through the interface between the semiconductor substrate 110 and the molding compound 270, to the top surface of the molding compound 270. In some embodiments, the dielectric layer 282 of the redistribution layer 280 (see FIG. 15) may cover the buffer material 261. The buffer material 261 may be formed by, for example, dispensing the buffer material 261 on a desired position after the process of FIG. 14 is complete and prior to the process of FIG. 15. The buffer material 261 may include a same material as the interface material 260 and may be formed using a similar way as the interface material 260, and thus relevant details are not repeated.

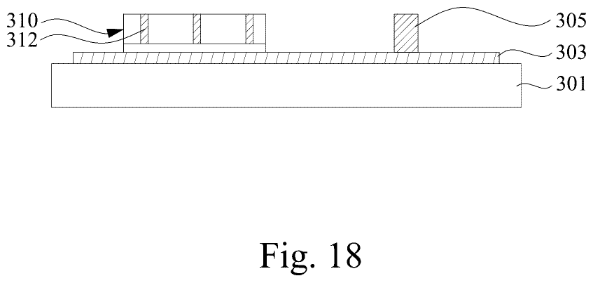

FIGS. 18 to 28 illustrate a method in various stages of forming a package structure in accordance with some embodiments of the present disclosure. Although FIGS. 18 to 28 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

Reference is made to FIG. 18. Shown there is a carrier substrate 301, and an adhesive layer 303 is formed over the carrier substrate 301. In some embodiments, the carrier substrate 301 includes glass, ceramic, or other suitable material to provide structural support during the formation of various features in device package. In some embodiments, the adhesive layer 303 may be a die attach film (DAF) which includes a polymer and in some embodiments comprises a thermoplastic material. The DAF may be liquid, e.g., a thick liquid, when applied but forms a solid at room temperature. The DAF material may become semi-liquid when heated and may become sticky to function as an adhesive at elevated temperatures. The DAF may comprise a polymer-based film that functions as an adhesive when heated, in some embodiments, for example. The DAF may comprise a thermoplastic material, such as epoxy resin, phenol resin, or poly-olefin, as examples, although alternatively, other thermoplastic materials or polymers compatible with semiconductor processing environments may be used.

At least one conductive via 305 is formed over the adhesive layer 303. In some embodiments, the material and the formation method of the conductive via 305 may be similar to those described with respect to the conductive vias 240 as discussed in FIG. 10, and thus relevant details will not be repeated for brevity. A semiconductor die 310 is attached on the adhesive layer 303. In some embodiments, the semiconductor die 310 may include conductive features 312 exposed from the front side of the semiconductor die 310.

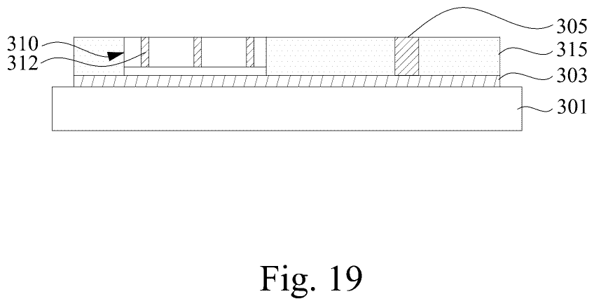

Reference is made to FIG. 19. A molding compound 315 is molded onto the adhesive layer 303 and surrounding the semiconductor die 310 and the conductive via 305. The top surface of molding compound 315 may be formed higher than, level with, or slightly lower than, the front surfaces of the semiconductor die 310 and the conductive via 305. Next, a grinding process may be performed to planarize the semiconductor die 310, the conductive via 305, and the molding compound 315. Accordingly, the top surfaces of the remaining portions of the molding compound 315 are level with the front surfaces of the semiconductor die 310 and the conductive via 305.

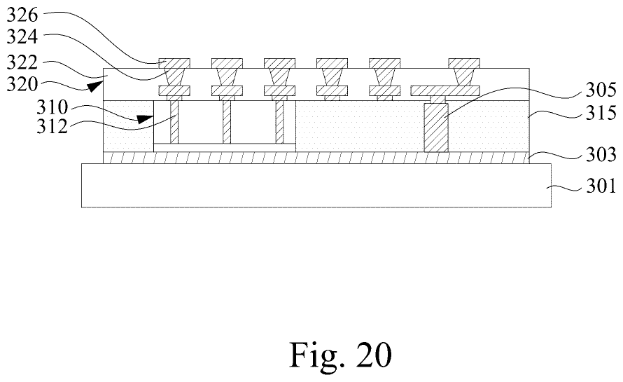

Reference is made to FIG. 20. A redistribution layer 320 is then formed over the molding compound 315. The redistribution layer 320 may include a dielectric layer 322 and conductive features 324 disposed in the dielectric layer 322. In some embodiments, the conductive features 324 may be electrically coupled to the conductive features 312 of the semiconductor die 310 and the conductive via 305. The redistribution layer 320 can include any number of dielectric layer(s) 322 and any number of conductive feature(s) 324. The redistribution layer 320 further includes conductive pads 326 disposed on the top surface of the redistribution layer 320 and electrically connected to the respective conductive features 324.

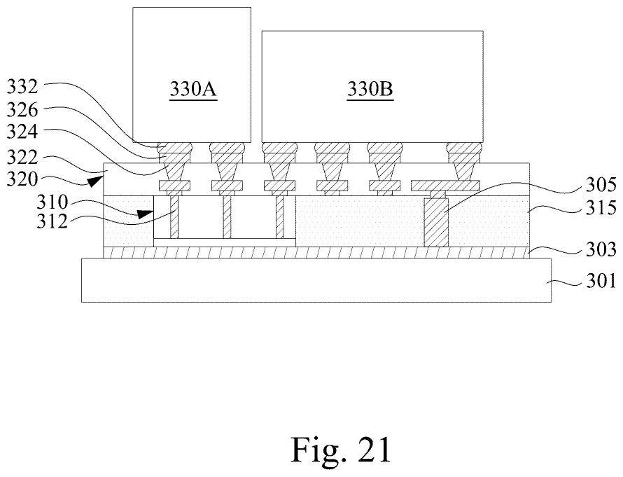

Reference is made to FIG. 21. Dies 330A and 330B are mounted over the redistribution layer 320. In some embodiments, the dies 330A and 330B may include a plurality of connectors 332, such as solder bumps. The connectors 332 of the dies 330A and 330B are disposed on the respective conductive pads 326, such that the dies 330A and 330B may be electrically connected to the redistribution layer 320.

In some embodiments, each of the dies 330A and 330B may be a package die, a device die, a die stack, and/or the like. The device die may be high performance integrated circuit, such as a System-on-Chip (SoC) die, a Central Processing Unit (CPU) die, a Graphic Processing Unit (GPU) die, field-programmable gate array (FPGA) die, a mobile application die, a memory die, or a die stack. In some embodiments, the memory die is a memory cube such as High Bandwidth Memory (HBM) die. For example, the die 330A is a HBM die, and the die 330B is a SoC die, while the disclosure is not limited thereto. In some embodiments, the dies 330A and 330B may include different heights. For example, the die 330A may include a greater height than the die 330B in some embodiments, while the disclosure is not limited thereto.

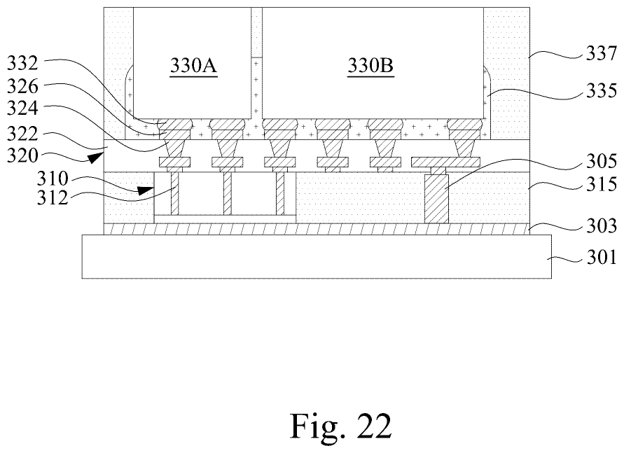

Reference is made to FIG. 22. An underfill material 335 is dispensed into the gaps between the dies 330A/330B and the redistribution layer 320. The underfill material 335 surrounds the connectors 332, and may extend up along sidewalls of the dies 330A and 330B. The underfill material 335 may be acceptable material, such as a polymer, epoxy, molding underfill, or the like. The underfill material 335 may be formed by a capillary flow process after the dies 330A and 330B are attached to the redistribution layer 320.

Molding compound 337 is formed over the redistribution layer 320 and surrounding the dies 330A and 330B. In some embodiments, the top surface of molding compound 337 is higher than the top surfaces of the dies 330A and 330B. Then, a planarization process such as a mechanical grinding step is performed to thin the molding compound 337 and the dies 330A and 330B. That is, both the molding compound 337 and the dies 330A and 330B are polished. As a result, top surface of the molding compound 337 may be level with top surfaces of the dies 330A and 330B. In some embodiments, the molding compound 337 may include a polymer, a resin, an epoxy, or the like.

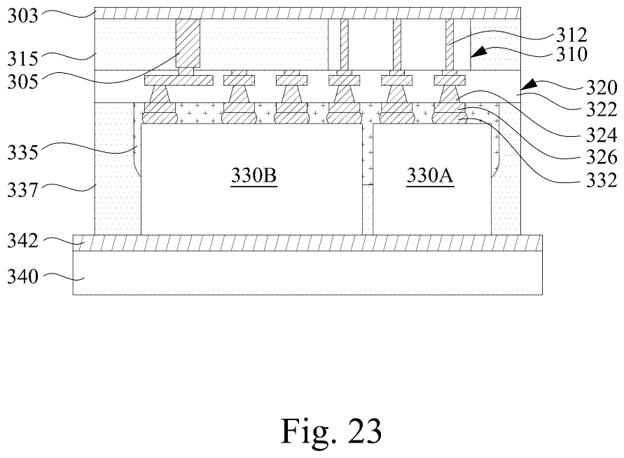

Reference is made to FIG. 23. The carrier substrate 301 is de-bonded from the adhesive layer 303. In some embodiments, the carrier substrate 301 may be peeled away from the adhesive layer 303. Then, the structure is flipped over by 180 degrees, and the structure is bonded to another carrier substrate 340 through an adhesive layer 342. The materials of the carrier substrate 340 and the adhesive layer 342 may be similar to those discussed with respect to the carrier substrate 301 and the adhesive layer 303, respectively, and thus relevant details will not be repeated for brevity.

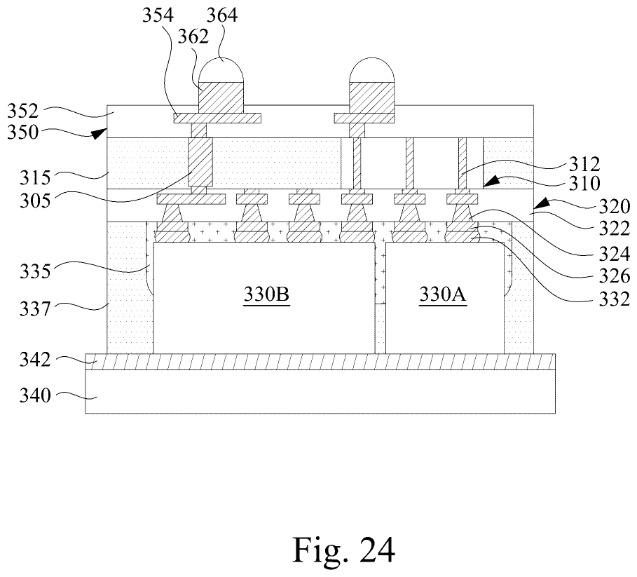

Reference is made to FIG. 24. A cleaning process (e.g., a DAF cleaning process) may be performed to remove remaining portions of the adhesive layer 303, such that the semiconductor die 310 and the molding compound 315 are exposed. Then, a planarization process such as a mechanical grinding step is performed to thin the molding compound 315 and the semiconductor die 310. In some embodiments, the planarization process may be performed until the conductive features 312 in the semiconductor die 310 and the conductive via 305 are exposed.

A redistribution layer 350 is then formed over the molding compound 315. The redistribution layer 350 may include a dielectric layer 352 and conductive features 354 disposed in the dielectric layer 352. In some embodiments, the conductive features 354 may be electrically coupled to the conductive features 312 of the semiconductor die 310 and the conductive via 305. The redistribution layer 320 can include any number of dielectric layer(s) 352 and any number of conductive feature(s) 354.

External connectors 362 may be formed over the redistribution layer 350 and may be electrically coupled to the conductive features 354 in the redistribution layer 350. In some embodiments, the external connectors 362 are copper pillars. Solders 364 are formed on the top surfaces of the respective external connectors 362.

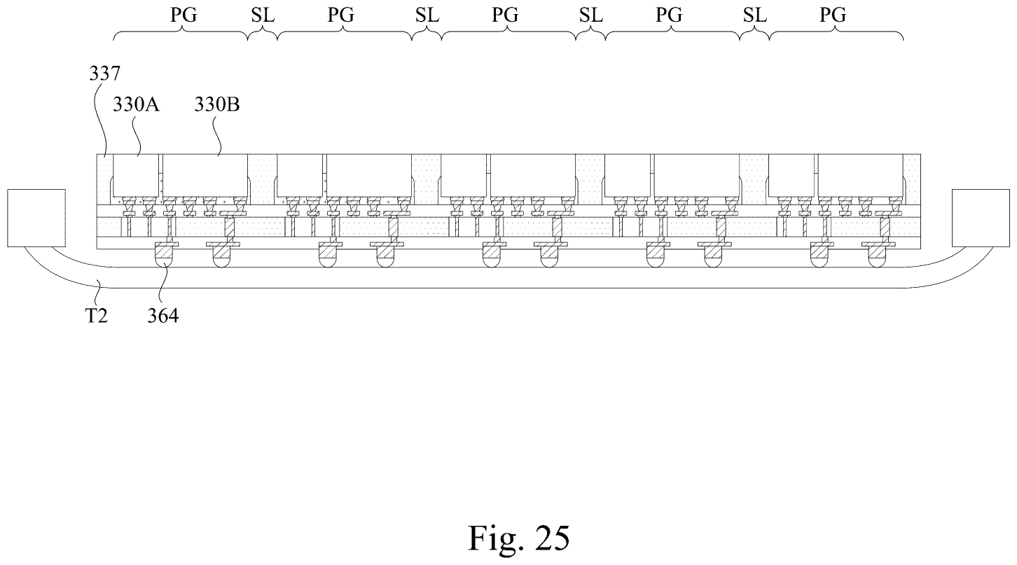

Reference is made to FIG. 25. The carrier substrate 340 is de-bonded from the adhesive layer 342, and the adhesive layer 342 is then removed to expose the dies 330A and 330B. Then, the package component is flipped over by 180 degrees, and is placed on a grooving tape T2. In greater detail, the solders 364 are in contact with the grooving tape T2, and the surfaces of the dies 330A and 330B face upwardly. It is noted that FIGS. 18 to 24 only illustrate a single package region, while in FIG. 25 the package component may include several package regions PG, in which the package regions PG may be separated by scribe lines SL.

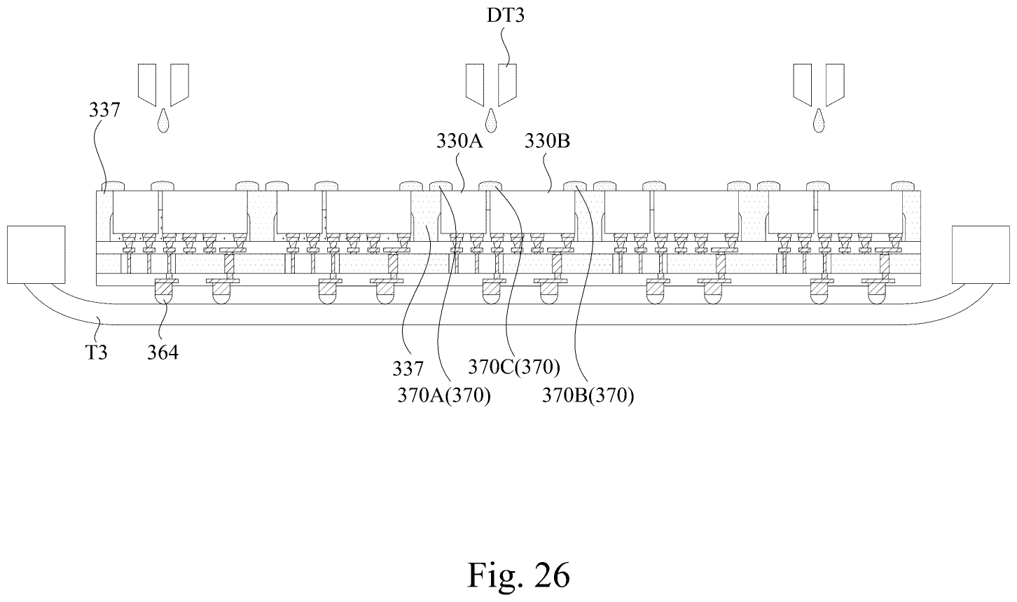

Reference is made to FIG. 26. Buffer materials 370 are dispensed over the molding compound 337. In greater detail, the buffer materials 370 may include a buffer material 370A that passes through the interface between the molding compound 337 and the die 330A. That is, the buffer material 370A may extend from the surface of the molding compound 337 to the surface of the dies 330A. The buffer materials 370 may also include a buffer material 370B that passes through the interface between the molding compound 337 and the die 330B. That is, the buffer material 370B may extend from the surface of the molding compound 337 to the surface of the dies 330B. The buffer materials 370 may also include a buffer material 370C that passes through both the interface between the molding compound 337 and the die 330A and the interface between the molding compound 337 and the die 330B. That is, the buffer material 370C may extend from the surface of the die 330A, passing through the surface of the molding compound 337, to the surface of the dies 330B. In some embodiments, the buffer materials 370 are separated from each other. That is, at least portions of the surfaces of the molding compound 337 and the dies 330A and 330B are free of coverage by the buffer materials 370.

In some embodiments, the buffer materials 370 are dispensed using a dispensing tool DT3. For example, the dispensing tool DT3 is moved to a desired position, and then a buffer material 370 is dispensed from the dispensing tool DT3. The dispensing tool DT3 is then moved to another position, and another buffer material 370 is dispensed from the dispensing tool DT3.

In some embodiments, the buffer materials 370 may include die attach film (DAF), polyimide (PI), acrylic base polymer, epoxy base polymer, or the like. In the embodiments where the buffer materials 370 are made of die attach film (DAF), the die attach films in liquid form are dispensed over the molding compound 337. Afterwards, an UV curing process is performed to slightly solidify the die attach films. A thermal curing process may then be performed to solidify the die attach films.

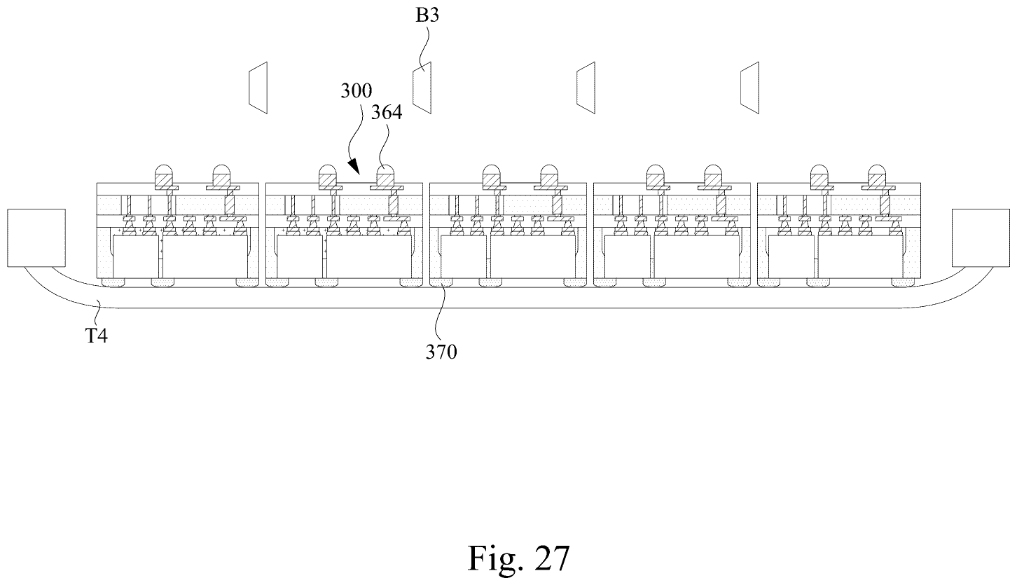

Reference is made to FIG. 27. After the buffer materials 370 are formed, the package component is flipped over by 180 degrees, and is placed on a grooving tape T3. In greater detail, the buffer materials 370 are in contact with the grooving tape T3, and the solders 364 face upwardly. Then, a cutting process may be performed through a dicing blade B3 along the scribe lines SL (see FIG. 25), so as to form several singulated package structures 300.

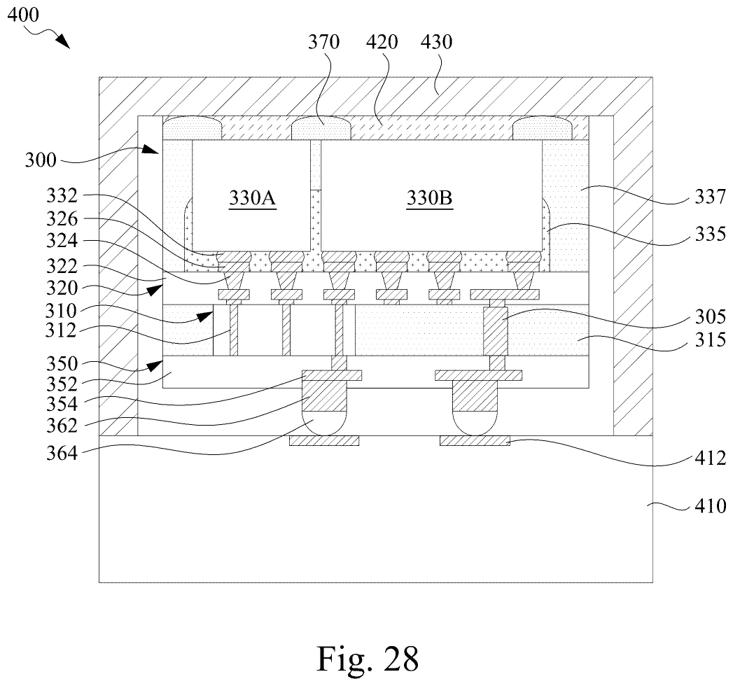

Reference is made to FIG. 28. The singulated package structure 300 is mounted over a semiconductor substrate 410. In greater detail, the solders 364 of the singulated package structure 300 is in contact with conductive pads 412 of the semiconductor substrate 410, such that the singulated package structure 300 may be electrically connected with the semiconductor substrate 410.

Afterwards, a heat-dissipating feature 430 is attached to the semiconductor substrate 410 and over the singulated package structure 300, so as to form a package structure 400. In some embodiments, the heat-dissipating feature 430 is a heat spreader lid and includes a plate portion and a wall portions vertically extending from the edge of the plate portion. In some embodiments, the heat-dissipating feature 430 has a high thermal conductivity, for example, between about 100 W/mK to about 500 W/mK or more, and may be made of a metal, a metal alloy, or the like. For example, the heat-dissipating feature 430 may include metals and/or metal alloys such as aluminum (Al), copper (Cu), nickel (Ni), cobalt (Co), combinations thereof, and the like. The heat-dissipating feature 160 may also be formed of a composite material, for example silicon carbide, aluminum nitride, graphite, and the like.

The heat-dissipating feature 430 may be mounted over the singulated package structure 300 through a thermal interface material 420. The thermal interface material 420 may surrounds the buffer materials 370 and in contact with the surfaces of the dies 330A and 330B, and the bottom surface of the heat-dissipating feature 430. In some embodiments, the buffer materials 370 may also be in contact with the bottom surface of the heat-dissipating feature 430. In some embodiments, the thermal interface material 420 may be a polymeric material, solder paste, indium solder paste, or the like.

During the formation of the package structure 400, the molding compound 337 may be formed surrounding the dies 330A and 330B. However, due to coefficient of thermal expansion (CTE) difference between the molding compound 337 and the dies 330A and 330B, material expansion may induce high stress at the interfaces between the molding compound 337 and the dies 330A and 330B. As a result, cracking or delamination may occur at these regions. Embodiments of the present disclosure provide a method by forming buffer materials 370 along the interfaces between the molding compound 337 and the dies 330A and 330B. The buffer materials 370 may release the stress at the interfaces, which in turn will reduce the possibility of cracking or delamination at these regions.

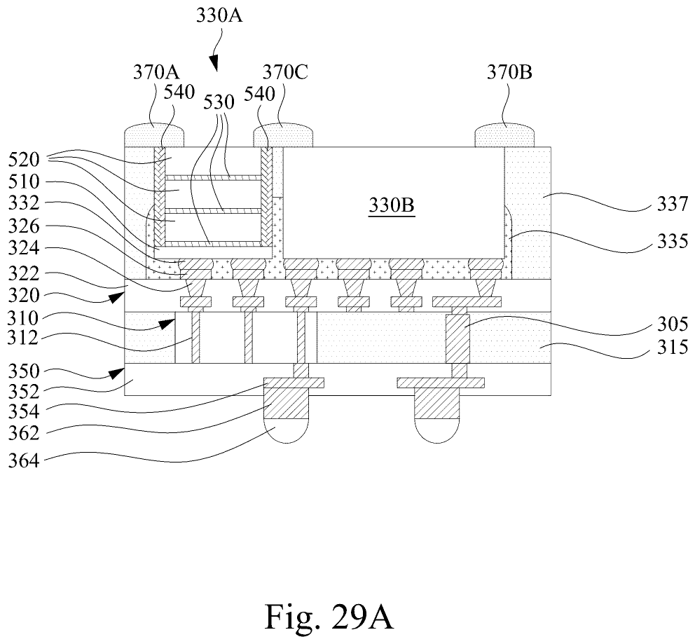

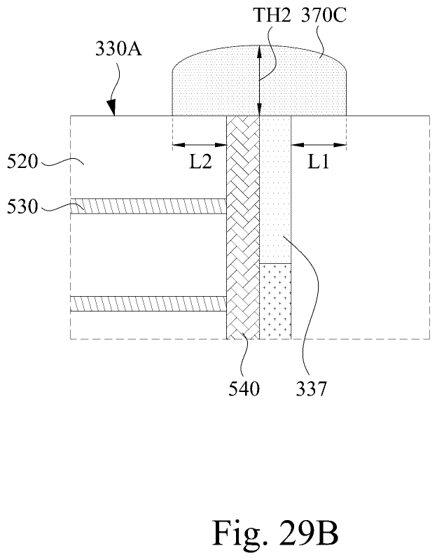

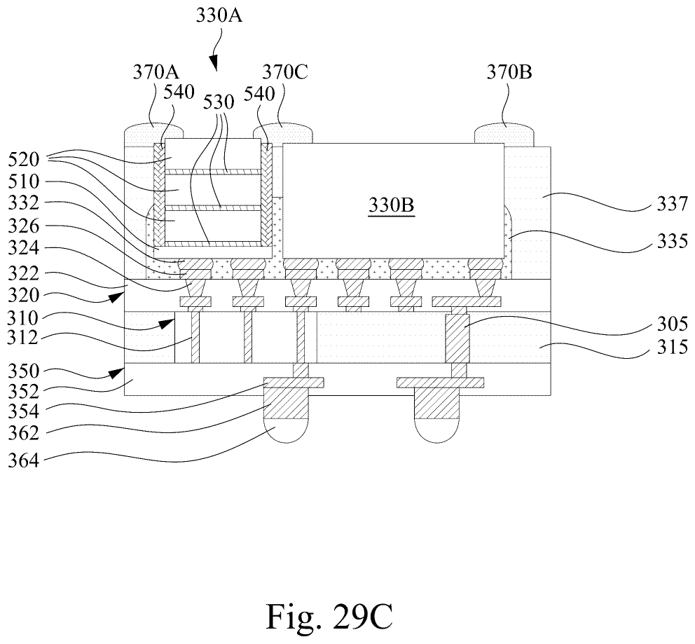

FIGS. 29A, 29B, and 29C are package structures in accordance with some embodiments of the present disclosure. In particular, FIGS. 29A, 29B, and 29C are enlarged view of the package structure 300 of FIG. 27.

In the embodiments of FIG. 29A, the die 330A may be a high bandwidth memory (HBM) die, and the die 330B may be a system on chip (SoC) die. In greater detail, the die 330A includes multiple semiconductor chips stacked on above another. For example, the die 330A includes a semiconductor chip 510 at the bottom, and a plurality of semiconductor chips 520 above the semiconductor chip 510. The semiconductor chips 510 and 520 are electrically connected with each other through conductive bonding structures 530. In some embodiments, each of the conductive bonding structures 530 includes metal pillars and/or solder bumps that are surrounded by an underfill material. In some embodiments, the die 330A includes a molding layer 540 over the semiconductor chip 510, encapsulates and protects the semiconductor chips 520. In some embodiments, the die 330B and the semiconductor chips 510 and 520 have silicon surface.

In FIG. 29A, the buffer material 370A is in contact with the molding compound 337, the molding layer 540 of the die 330A, and the topmost semiconductor chip 520 of the die 330A. The buffer material 370C is in contact with the molding compound 337, the molding layer 540 of the die 330A, the topmost semiconductor chip 520 of the die 330A, and the die 330B. The buffer material 370B is in contact with the molding compound 337 and the die 330B.

FIG. 29B is an enlarged view of FIG. 29A. In greater detail, the buffer material 370C has a thickness TH2. The buffer material 370C and the die 330A have a contact length L1, and the buffer material 370C and the topmost semiconductor chip 520 have a contact length L2. In some embodiments, the thickness TH2 is in a range from about 5 μm to about 50 μm. If the thickness TH2 is too small (e.g., much smaller than 5 μm), the buffer material 370C may not be able to prevent cracking or delamination at the heterogeneous interfaces among the molding compound 337 and the dies 330A and 330B. If the thickness TH2 is too large (e.g., much greater than 50 μm), no significant improvement is obtained. In some embodiments, the contact lengths L1 and L2 may be smaller than 100 μm. This will ensure that the die 330B and the topmost semiconductor chip 520 may be in contact with a following formed thermal interface material (e.g., the thermal interface material 420 of FIG. 28), and thus heat dissipation may be improved.

In the embodiments of FIG. 29C, the top surfaces of the molding compound 337, the topmost semiconductor chip 520, the molding layer 540, and the die 330B may at different levels. This is because, although a planarization process may be performed during forming the molding compound 337 (see FIG. 22), the planarization process may include different polishing rates on different materials, and thus the resulting structure is shown in FIG. 29C. In some embodiments, the topmost semiconductor chip 520 may protrude from the molding layer 540, the molding layer 540 and the die 330B may protrude from the molding compound 337. As a result, the buffer material 370A may be in contact with sidewalls of the molding layer 540 and the topmost semiconductor chip 520. The buffer material 370A may be in contact with sidewalls of the molding layer 540 and the topmost semiconductor chip 520. The buffer material 370C may be in contact with sidewalls of the molding layer 540, the topmost semiconductor chip 520, and the die 330B. The buffer material 370B may be in contact with sidewall of the die 330B.

According to the aforementioned embodiments, it can be seen that the present disclosure offers advantages in fabricating integrated circuits. It is understood, however, that other embodiments may offer additional advantages, and not all advantages are necessarily disclosed herein, and that no particular advantage is required for all embodiments. Embodiments of the disclosure provide forming buffer materials at heterogeneous interfaces among different elements of a package structure. The buffer materials may release high stress at the heterogeneous interfaces, which in turn will reduce the possibility of cracking or delamination at these regions.

In some embodiments of the present disclosure, a package structure includes a semiconductor die. An underfill material is below the semiconductor die and extends up to a sidewall of the semiconductor die. A molding compound surrounds the semiconductor die and the underfill material. An interface material is between the molding compound and the underfill material.

In some embodiments, the interface material extends to the sidewall of the semiconductor die.

In some embodiments, a top end of the interface material is substantially level with a top surface of the semiconductor die.

In some embodiments, the package structure further includes a redistribution layer, in which the semiconductor die is disposed on the redistribution layer, and the interface material extends to a top surface of the redistribution layer.

In some embodiments, the interface material comprises a top portion, a middle portion, and a bottom portion, and the middle portion is thicker than the top portion and the bottom portion.

In some embodiments, the package structure further includes a buffer material covering a corner of the semiconductor die, wherein the underfill material is in contact with the buffer material.

In some embodiments, the buffer material is separated from the interface material through the underfill material.

In some embodiments of the present disclosure, a package structure includes a semiconductor substrate and a package disposed over the semiconductor substrate. The package includes a first die, a molding compound surrounding the first die, in which a top surface of the first die is exposed through the molding compound, and a first buffer material extending from a top surface of the molding compound to the top surface of the first die.

In some embodiments, portions of the top surface of the molding compound and the top surface of the first die are free of coverage by the first buffer material.

In some embodiments, the first buffer material is made of a die attach film (DAF), a polyimide (PI), an acrylic base polymer, or an epoxy base polymer.

In some embodiments, the package structure further includes a heat dissipation feature mounted over the package through a thermal interface material, wherein the thermal interface material surrounds the first buffer material.

In some embodiments, the first buffer material is in contact with the heat dissipation feature.

In some embodiments, the package further includes a second die adjacent to the first die, in which a top surface of the first die is exposed through the molding compound. A second buffer material extends from the top surface of the molding compound to the top surface of the second die.

In some embodiments, the first buffer material is spaced apart from the second buffer material.

In some embodiments, the second buffer material extends from the top surface of the second die, passing through the top surface of the molding compound, to the top surface of the first die.

In some embodiments of the present disclosure, a method includes forming an interconnect structure over a substrate; performing a bevel cutting process to form grooves through a top surface of the substrate; dispensing buffer materials in the grooves, respectively; and performing a singulation process thorough the grooves of the substrate to form a plurality of dies.

In some embodiments, the buffer materials are separated from each other.

In some embodiments, the singulation process cuts through the buffer materials.

In some embodiments, the buffer materials are dispensed in a liquid form, and the method further includes performing an UV curing process to the buffer materials; and performing a thermal curing process to the buffer materials.

In some embodiments, each of the plurality of dies comprise a top surface, a sidewall, and a chamfered edge connecting the top surface and the sidewall, and one of the buffer materials extends from the top surface of the plurality of dies to the chamfered edge of the plurality of dies.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a semiconductor die;
an underfill material below the semiconductor die and extending up to a sidewall of the semiconductor die;
a molding compound surrounding the semiconductor die and the underfill material; and
an interface material between the molding compound and the underfill material.

2. The package structure of claim 1, wherein the interface material extends to the sidewall of the semiconductor die.

3. The package structure of claim 1, wherein a top end of the interface material is substantially level with a top surface of the semiconductor die.

4. The package structure of claim 1, further comprising a redistribution layer, wherein the semiconductor die is disposed on the redistribution layer, and the interface material extends to a top surface of the redistribution layer.

5. The package structure of claim 1, wherein the interface material comprises a top portion, a middle portion, and a bottom portion, and the middle portion is thicker than the top portion and the bottom portion.

6. The package structure of claim 1, further comprising a buffer material covering a corner of the semiconductor die, wherein the underfill material is in contact with the buffer material.

7. The package structure of claim 6, wherein the buffer material is separated from the interface material through the underfill material.

8. A package structure, comprising:
a semiconductor substrate;
a package disposed over the semiconductor substrate, wherein the package comprises:
a first die;
a molding compound surrounding the first die, wherein a top surface of the first die is exposed through the molding compound; and
a first buffer material extending from a top surface of the molding compound to the top surface of the first die.

9. The package structure of claim 8, wherein portions of the top surface of the molding compound and the top surface of the first die are free of coverage by the first buffer material.

10. The package structure of claim 8, wherein the first buffer material is made of a die attach film (DAF), a polyimide (PI), an acrylic base polymer, or an epoxy base polymer.

11. The package structure of claim 8, further comprising a heat dissipation feature mounted over the package through a thermal interface material, wherein the thermal interface material surrounds the first buffer material.

12. The package structure of claim 11, wherein the first buffer material is in contact with the heat dissipation feature.

13. The package structure of claim 8, wherein the package further comprises:
a second die adjacent to the first die, wherein a top surface of the first die is exposed through the molding compound; and
a second buffer material extending from the top surface of the molding compound to the top surface of the second die.

14. The package structure of claim 13, wherein the first buffer material is spaced apart from the second buffer material.

15. The package structure of claim 13, wherein the second buffer material extends from the top surface of the second die, passing through the top surface of the molding compound, to the top surface of the first die.

16. A method, comprising:
forming an interconnect structure over a substrate;
performing a bevel cutting process to form grooves through a top surface of the substrate;
dispensing buffer materials in the grooves, respectively; and
performing a singulation process thorough the grooves of the substrate to form a plurality of dies.

17. The method of claim 16, wherein the buffer materials are separated from each other.

18. The method of claim 16, wherein the singulation process cuts through the buffer materials.

19. The method of claim 16, wherein the buffer materials are dispensed in a liquid form, and the method further comprises:
performing an UV curing process to the buffer materials; and
performing a thermal curing process to the buffer materials.

20. The method of claim 16, wherein each of the plurality of dies comprise a top surface, a sidewall, and a chamfered edge connecting the top surface and the sidewall, and one of the buffer materials extends from the top surface of the plurality of dies to the chamfered edge of the plurality of dies.
